(19) United States
(12) Patent Application Publication
(10) Pub. No.: US 2008/0292986 A1
(43) Pub. Date: Nov. 27, 2008

(54) INKJET PRINTHEAD AND METHOD OF MANUFACTURING THE SAME

(75) Inventors: Byung-ha PARK, Suwon-si (KR); Young-ung Ha, Suwon-si (KR)

Correspondence Address: STANZIONE & KIM, LLP, 919 18TH STREET, N.W., SUITE 440, WASHINGTON, DC, 20006, US

(73) Assignee: Samsung Electronics Co., Ltd., Suwon-si (KR)

(21) Appl. No.: 12/028,075

(22) Filed: Feb. 8, 2008

(30) Foreign Application Priority Data
May 22, 2007 (KR) 2007-49959

(51) Int. Cl. G03F 7/20; G03C 1/04; B41J 2/05

(52) U.S. Cl. 430/270.1; 347/62; 430/320

(57) ABSTRACT

A method of manufacturing an inkjet printhead having a small thickness variation and having excellent durability, and an inkjet printhead manufactured by the same.

### CROSS-REFERENCE TO RELATED APPLICATIONS

This application claims priority under 35 U.S.C. §119(a) from Korean Patent Application No. 10-2007-0049959, filed on May 22, 2007, in the Korean Intellectual Property Office, the disclosure of which is incorporated herein in its entirety by reference.

### BACKGROUND OF THE INVENTION

1. Field of the Invention

The present general inventive concept relates to a printhead and a method of manufacturing the same, and more particularly, to a method of manufacturing an inkjet printhead having a small thickness variation and having excellent durability, where a shape and dimension of an ink passage of the inkjet printhead can be easily controlled, and thus, a uniformity of the ink passage is improved, and where modification of the ink passage is small, and an inkjet printhead manufactured by the same.

2. Description of the Related Art

In general, inkjet printheads eject fine droplets of ink to print at desired positions on a recording medium to print an image of a predetermined color. The inkjet printheads can be classified into two types according to a mechanism of ejecting an ink droplet. One is a thermally-driven type inkjet printhead which generates a bubble in the ink using a heat source to eject an ink droplet by an expansion force of the bubble. The other one is a piezoelectric type inkjet printhead which ejects an ink droplet by pressure applied to the ink by a deformation of a piezoelectric body. However, the only difference between the two types of inkjet printheads is the driving device to eject an ink droplet, and the two types of inkjet printheads are the same in that they eject ink droplets using a constant energy.

A conventional structure of a thermally-driven inkjet printhead is illustrated in FIG. 1.

Referring to FIG. 1, an inkjet printhead includes a substrate 10, a passage forming layer 20 stacked on the substrate 10, and a nozzle plate 30 formed on the passage forming layer 20. An ink supply hole 51 is formed in the substrate 10. The passage forming layer 20 has an ink chamber 53 storing ink, and a restrictor 52 connecting the ink supply hole 51 and the ink chamber 53. The nozzle layer 30 has a nozzle 54 through which the ink is ejected from the ink chamber 53. Also, the substrate 10 has a heater 41 for heating ink in the ink chamber 53, and an electrode 42 for supplying current to the heater 41.

The ink ejection mechanism of the conventional thermally-driven inkjet printhead having the above-described configuration will now be described. Ink is supplied from an ink reservoir (not illustrated) to the ink chamber 53 through the ink supply hole 51 and the restrictor 52. The ink filled in the ink chamber 53 is heated by the heater 41 consisting of resistive heating elements. The ink boils to form bubbles and the bubbles expand so as to press the ink in the ink chamber 53. Accordingly, the ink in the ink chamber 53 is ejected outside the ink chamber 53 through the nozzle 54 in the form of ink droplets.

As an example of a method of fabricating an inkjet printhead, U.S. Pat. No. 5,738,799 discloses a method of fabricating an inkjet printhead including forming photoresist molding on a silicon substrate, coating a photosensitive epoxy resin on the formed photoresist molding to form a nozzle, opening a feed hole, and opening the photoresist molding in order to form a passage. However, according to this method, due to a step difference of the molding, a thickness difference of a nozzle layer formed on the molding occurs. In addition, it is difficult to achieve a desired passage thickness, and the durability of the epoxy resin is reduced.

U.S. Pat. No. 6,739,519 discloses another method of fabricating an inkjet printhead including forming an ink chamber and a channel on a silicon substrate using a SU-8 resin, filling the formed ink chamber and channel with a sacrificial layer material, planarizing the sacrificial layer, forming a nozzle using the SU-8 resin, removing the sacrificial layer material, and forming an ink supply hole. However, according to this method, adhesion of a nozzle layer and the like to a substrate is weak, and a resist structure may easily be cracked, thus lowering a durability of the structure.

### SUMMARY OF THE INVENTION

The present general inventive concept provides a negative photoresist composition that can be used to manufacture an inkjet printhead having improved durability and the like.

The present general inventive concept also provides a method of manufacturing an inkjet printhead using the negative photoresist composition.

The present general inventive concept also provides an inkjet printhead manufactured by the same.

Additional aspects and utilities of the present general inventive concept will be set forth in part in the description which follows and, in part, will be obvious from the description, or may be learned by practice of the general inventive concept

The foregoing and/or other aspects and utilities of the present general inventive concept are achieved by providing a negative photoresist composition including a bisphenol-A-based prepolymer having oxytein functional groups on repeating monomer units thereof, a cationic photo initiator, and a solvent.

Amounts of the cationic photo initiator and the solvent may be 1-10 parts by weight and 30-300 parts by weight, respectively, based on 100 parts by weight of the bisphenol-A-based prepolymer.

The bisphenol-A-based prepolymer may be a prepolymer represented by Formula 1 below:

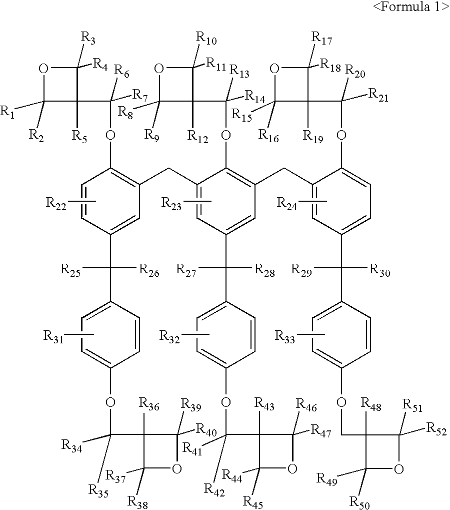

wherein n may be an integer of 1-20, and R₁ through R₅₂ may each independently be one of a halogen atom, a carboxyl group, an amino group, a nitro group, a cyano group, a substituted or unsubstituted C₁-C₂₀ alkyl group, a substituted or unsubstituted C₁-C₂₀ alkoxy group, a substituted or unsubstituted C₂-C₂₀ alkenyl group, a substituted or unsubstituted C₂-C₂₀ alkynyl group, a substituted or unsubstituted C₁-C₂₀ heteroalkyl group, a substituted or unsubstituted C₆-C₃₀ aryl group, a substituted or unsubstituted C₇-C₃₀ arylalkyl group, a substituted or unsubstituted C₅-C₃₀ heteroaryl group, and a substituted or unsubstituted C₃-C₃₀ heteroarylalkyl group.

The bisphenol-A-based prepolymer of Formula 1 may be a prepolymer represented by Formula 2 below:

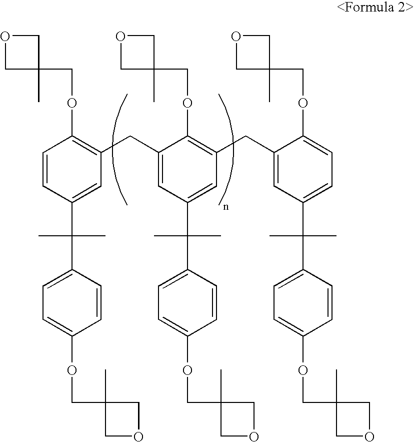

wherein n may be an integer of 1-20.

The cationic photo initiator may be one of an aromatic halonium salt and an aromatic sulfonium salt.

The solvent may be at least one selected from a group consisting of γ-butyrolactone, propylene glycol methyl ethyl acetate, tetrahydrofurane, methyl ethyl ketone, methyl isobutyl ketone, cyclophentanone, and xylene.

The foregoing and/or other aspects and utilities of the present general inventive concept are also achieved by providing a method of manufacturing an inkjet printhead, the method including forming a heater to heat ink and an electrode to supply current to the heater on a substrate, coating a first negative photoresist composition on the substrate on which the heater and the electrode are formed, and patterning the first negative photoresist composition by photolithography to form a passage forming layer that defines an ink passage, forming a sacrificial layer on the substrate on which the passage forming layer is formed to cover the passage forming layer, planarizing top surfaces of the passage forming layer and the sacrificial layer by a polishing process, coating a second negative photoresist composition on the passage forming layer and the sacrificial layer, and patterning the second negative photoresist composition by photolithography to form a nozzle layer having a nozzle, forming an ink supply hole in the substrate, and removing the sacrificial layer, wherein the first and second negative photoresist compositions may each independently be negative photoresist compositions including a bisphenol-A-based prepolymer having oxytein functional groups on repeating monomer units thereof, a cationic photo initiator and a solvent.

The polishing process may be a chemical mechanical polishing (CMP) process.

The substrate may be a silicon wafer.

The forming of the passage forming layer may include coating the first negative photoresist composition on an entire surface of the substrate to form a first photoresist layer, exposing the first photoresist layer to light using a first photo mask having an ink passage pattern, and developing the first photoresist layer to remove an unexposed portion of the first photoresist layer to form the passage forming layer.

The sacrificial layer may include one of a positive photoresist and non-photosensitive soluble polymer.

The positive photoresist may be an imide-based positive photoresist.

The non-photosensitive soluble polymer may be at least one selected from a group consisting of a phenol resin, a polyurethane resin, an epoxy resin, a polyimide resin, an acryl resin, a polyamide resin, a urea resin, a melamin resin, and a silicone resin.

In the forming of the sacrificial layer, a height of the sacrificial layer may be greater than that of the passage forming layer.

In the forming of the sacrificial layer, the sacrificial layer may be formed by spin coating.

The planarizing of the top surfaces of the passage forming layer and the sacrificial layer may include polishing the top surfaces of the passage forming layer and the sacrificial layer using a polishing process until the ink passage has a desired height.

The forming of the nozzle layer may include coating the second negative photoresist composition onto the passage forming layer and the sacrificial layer to form a second photoresist layer, exposing the second photoresist layer to light using a second photo mask having a nozzle pattern, and developing the second photoresist layer to remove an unexposed portion of the second photoresist layer to form the nozzle and the nozzle layer.

The forming of the ink supply hole may include coating a photoresist onto a rear surface of the substrate, patterning the photoresist to form an etching mask for forming the ink supply hole, and etching a rear surface of the substrate that is exposed by the etching mask to form the ink supply hole.

The rear surface of the substrate may be etched by dry etching with plasma.

The rear surface of the substrate may be etched by wet etching using one of tetramethyl ammonium hydroxide (TMAH) and KOH as an etchant.

The foregoing and/or other aspects and utilities of the present general inventive concept are also achieved by providing an inkjet printhead manufactured a method of manufacturing an inkjet printhead using a negative photoresist composition comprising a bisphenol-A-based prepolymer having oxytein functional groups on repeating units thereof, the method including forming a heater to heat ink and an electrode to supply current to the heater on a substrate, coating a first negative photoresist composition on the substrate on which the heater and the electrode are formed, and patterning the first negative photoresist composition by photolithography to form a passage forming layer that defines an ink passage, forming a sacrificial layer on the substrate on which the passage forming layer is formed to cover the passage forming layer, planarizing top surfaces of the passage forming layer and the sacrificial layer by a polishing process, coating a second negative photoresist composition on the passage forming layer and the sacrificial layer, and patterning the second negative photoresist composition by photolithography to form a nozzle layer having a nozzle, forming an ink supply hole in the substrate, and removing the sacrificial layer, wherein the first and second negative photoresist compositions are each independently negative photoresist compositions including the bisphenol-A-based prepolymer having oxytein functional groups on repeating units thereof, a cationic photo initiator, and a solvent.

The foregoing and/or other aspects and utilities of the present general inventive concept are also achieved by providing an inkjet printhead, including a chamber layer to define an ink passage, the ink passage defining a plurality of ink chambers and restrictors, and a nozzle layer defining a plurality of nozzles, the nozzles disposed to correspond to the plurality of ink chambers, wherein the chamber layer and the nozzle layer are each independently formed of a negative photoresist including a bisphenol-A-based prepolymer having oxytein functional groups on repeating units thereof, a cationic photo initiator, and a solvent.

The chamber layer may be formed by coating a first negative photoresist composition on a substrate, and patterning the first negative photoresist composition by photolithography to form the chamber layer, and the nozzle layer may be formed by coating a second negative photoresist composition on the chamber layer, and patterning the second negative photoresist composition by photolithography to form the nozzle layer.

### BRIEF DESCRIPTION OF THE DRAWINGS

These and/or other aspects and utilities of the present general inventive concept will become apparent and more readily appreciated from the following description of the embodiments, taken in conjunction with the accompanying drawings of which:

FIG. 1 is a sectional view illustrating a conventional structure of a thermally-driven type inkjet printhead;

FIGS. 2A through 2L are sectional views illustrating a method of manufacturing an inkjet printhead according to an embodiment of the present general inventive concept;

FIG. 3 is an optical microscopic image of 20 μm line/space (L/S) patterns of oxetan photoresist prepared according to an embodiment of the present general inventive concept;

FIG. 4 is an electronic microscopic image of an ink supply hole existing on a rear surface of an inkjet printhead manufactured according to an embodiment of the present general inventive concept;

FIG. 5 is an electronic microscopic image of a nozzle layer of an inkjet printhead manufactured according to an embodiment of the present general inventive concept; and

FIG. 6 is a scanning electron microscopic (SEM) image of 20 μm line/space (L/S) patterns of oxetan photoresist prepared according to an embodiment of the present general inventive concept.

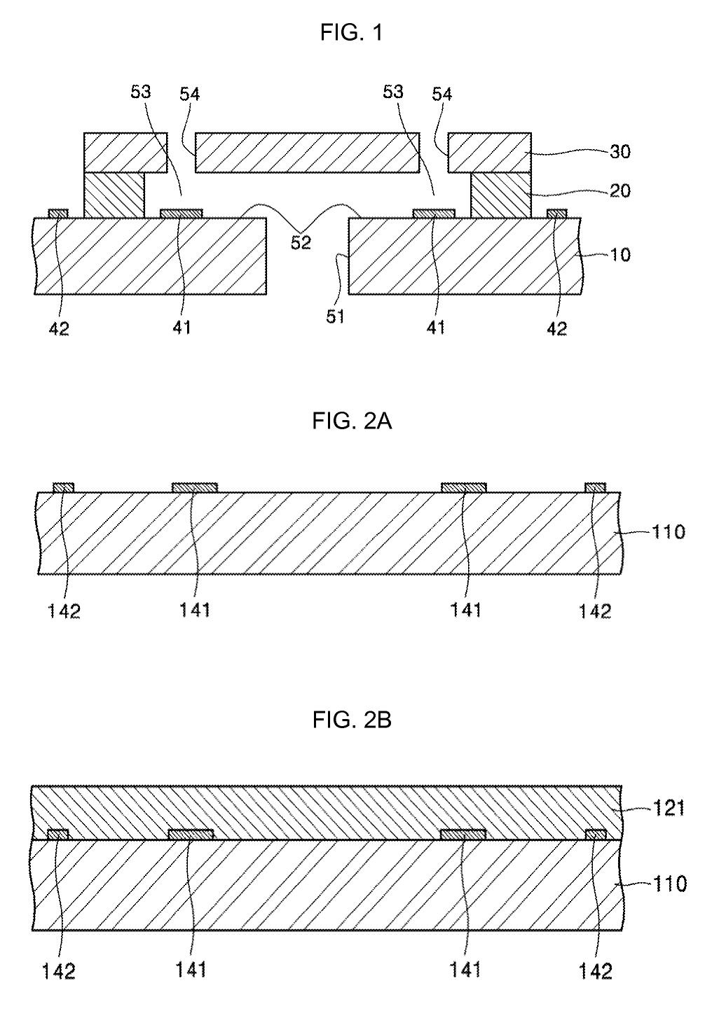

### DETAILED DESCRIPTION OF THE PREFERRED EMBODIMENTS

The present general inventive concept provides a method of manufacturing an inkjet printhead and an inkjet printhead manufactured by the same. The inkjet printhead has a reduced thickness difference and improved durability by using bisphenol-A-based prepolymer having an oxytein functional group on a repeating unit thereof as a prepolymer which forms a cross-linked polymer layer. In particular, since a top surface of a sacrificial layer can be planarized, a shape and dimension of an ink passage can be easily controlled, thereby improving uniformity of the ink passage. Also, since gas is not generated in the sacrificial layer, deformation of a nozzle layer due to gas can be avoided.

Reference will now be made in detail to the embodiments of the present general inventive concept, examples of which are illustrated in the accompanying drawings, wherein like reference numerals refer to the like elements throughout. The embodiments are described below in order to explain the present general inventive concept by referring to the figures. In the figures, the dimension or thickness of each element can be exaggerated for clarity. It will also be understood that when a layer is referred to as being “on” a substrate or another layer, it can be directly on the substrate or other layer, or intervening layers may also be present. Hereinafter, a thermally driven type inkjet printhead will be mainly described. However, the present general inventive concept can also be applied to a piezoelectric-driven type printhead, and further to a monolithic type inkjet printhead and a multi-layer type inkjet printhead. In addition, while the following figures illustrate a very small portion of a silicon wafer, an inkjet printhead according to the present general inventive concept can be manufactured in the form of tens to hundreds of chips on a single wafer.

A nozzle layer according to the present general inventive concept may include cross-linked polymers that are negative photoresists. The cross-linked polymers can be prepared by cross-linking bisphenol-A-based prepolymers having a plurality of oxytein functional groups. Oxytein multi-functional groups are generally arranged at sites of hydrogen atoms of phenolic hydroxyl groups. The prepolymers can form cross-linked polymers by exposure to light, and form a film with a high cross-linking density. Thus, a resolution is increased, and swelling by ink or a solvent can be prevented.

The bisphenol-A-based prepolymer having oxytein functional groups on repeating units thereof may be a prepolymer represented by Formula 1 below:

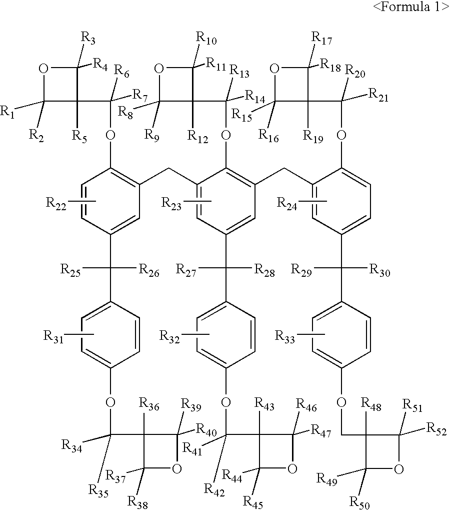

wherein n is an integer of 1-20, and R₁ through R₅₂ are each independently one of a halogen atom, a carboxyl group, an amino group, a nitro group, a cyano group, a substituted or unsubstituted C₁-C₂₀ alkyl group, a substituted or unsubstituted C₁-C₂₀ alkoxy group, a substituted or unsubstituted C₂-C₂₀ alkenyl group, a substituted or unsubstituted C₂-C₂₀ alkynyl group, a substituted or unsubstituted C₁-C₂₀ heteroalkyl group, a substituted or unsubstituted C₆-C₃₀ aryl group, a substituted or unsubstituted C₇-C₃₀ arylalkyl group, a substituted or unsubstituted C₅-C₃₀ heteroaryl group, and a substituted or unsubstituted C₃-C₃₀ heteroarylalkyl group.

The bisphenol-A-based prepolymer of Formula 1 may be a prepolymer represented by Formula 2 below:

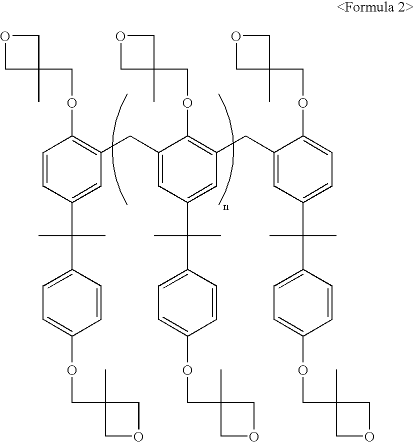

wherein n is an integer of 1-20.

Among the substituents used herein, the alkyl group may be a linear or branched C₁-C₂₀ alkyl group, more preferably a linear or branched C₁-C₁₂ alkyl group, and most preferably a linear or branched C₁-C₆ alkyl group. Examples of the alkyl group include methyl, ethyl, n-propyl, isopropyl, n-butyl, isobutyl, sec-butyl, t-butyl, pentyl, isoamyl, hexyl and the like. At least one hydrogen atom contained in these alkyl groups can be further substituted with a halogen atom to form a haloalkyl group.

The alkoxy group used herein may be an oxygen-containing linear or branched alkoxy group having C₁-C₂₀ alkyl group, more preferably an alkoxy group having 1-6 carbon atoms, and even more preferably an alkoxy group having 1-3 carbon atoms. Examples of the alkoxy group include methoxy, ethoxy, propoxy, butoxy and t-butoxy. The alkoxy group can be further substituted with at least one halo atom, such as fluoro, chloro, or bromo, to form a haloalkoxy group. Examples of the haloalkoxy group include fluoromethoxy, chloromethoxy, trifluoromethoxy, trifluoroethoxy, fluoroethoxy and fluoropropoxy and the like.

The alkenyl group used herein refers to a linear or branched C₂-C₂₀ aliphatic hydrocarbon group containing a carbon-carbon double bound. The alkenyl group may have 2-12 carbon atoms in a chain, and more preferably 2-6 carbon atoms in a chain. The branched alkenyl group refers to an alkenyl group in which at least one lower alkyl group or lower alkenyl group is attached to a straight alkenyl chain. The alkenyl group may be unsubstituted or substituted by at least one substituent selected from halo, carboxyl, hydroxyl, formyl, sulfo, sulfino, carbamoyl, amino and imino, but is not limited to these substituents. Examples of the alkenyl group include ethenyl, prophenyl, carboxyethenyl, carboxyprophenyl, sulfinoethenyl, sulfonoethenyl and the like.

The alkynyl group used herein refers to a linear or branched C₂-C₂₀ aliphatic hydrocarbon group having a carbon-carbon triple bond. The alkynyl group may have 2-12 carbon atoms in a chain, and more preferably 2-6 carbon atoms in a chain. The branched alkynyl group refers to an alkynyl group in which at least one lower alkyl group or lower alkynyl group is attached to a straight alkynyl chain. The alkynyl group may be unsubstituted, or substituted by at least one substituents selected from halo, carboxyl, hydroxyl, formyl, sulfo, sulfino, carbamoyl, amino and imino, but is not limited to the substituents.

The heteroalkyl group used herein refers to a group containing a hetero atom, such as N, O, P, S or the like, in a main chain of the alkyl group described above with 1-20 carbon atoms, preferably 1-12 carbon atoms, and more preferably 1-6 carbon atoms.

The aryl group used herein can be used alone or in combination, and refers to C₆-C₃₀ carbocyclic aromatic system containing at least one ring. The rings can be attached to each other using a pendant method or fused with each other. The term “aryl” refers to an aromatic radical, such as phenyl, naphthyl, tertrahydronaphthyl, indane and biphenyl, and preferably phenyl. The aryl group can have 1-3 substituents, such as hydroxy, halo, haloalkyl, nitro, cyano, alkoxy, and low-level alkylamino.

The arylalkyl group used herein refers to a group in which at least one hydrogen atom of the alkyl group described above is substituted with the aryl group described above.

The heteroaryl group used herein refers to a monovalent monocyclic or bicyclic aromatic radical having 5-30 carbon atoms and containing one, two, or three hetero atoms selected from N, O, and S. In addition, the term “heteroaryl group” refers to a monovalent monocyclic or bicyclic aromatic radical in which a hetero atom in a ring is oxidized or quaternized to form, for example, N-oxide or quaternary salts. Examples of the heteroaryl group include thienyl, benzothienyl, pyridyl, pyrazinyl, pyrimidinyl, pyridazinyl, quinolinyl, quinoxalinyl, imidazolyl, furanyl, benzofuranyl, thiazolyl, isoxazoline, benzisoxazoline, benzimidazolyl, triazolyl, pyrazolyl, pyrolyl, indolyl, 2-pyridonyl, N-alkyl-2-pyridonyl, pyrazinonyl, pyridazinonyl, pyrimidinonyl, oxazolonyl and corresponding N-oxides thereof (for example, pyridyl N-oxide, quinolinyl N-oxide), quaternary salts thereof, and the like, but are not limited thereto.

The heteroarylalkyl group used herein refers to a C₃-C₃₀ carbocyclic aromatic system in which at least hydrogen atom of the alkyl group as defined above is substituted with the heteroaryl group as defined above.

A cationic photo initiator contained in a negative photoresist composition according to the present general inventive concept may be generally a photo initiator that generates ions or free radicals that initiate polymerization during exposure to light. Examples of the cationic photo initiator include an aromatic halonium salt or a sulfonium salt of a Group VA or VI element, and the like.

Examples of the aromatic sulfonium salt include triphenylsulfonium tetrafluoroborate, triphenylsulfonium hexafluoroantimonate (UVI-6974 obtained from Union Carbide), phenylmethylbenzylsulfonium hexafluoroantimonate, phenylmethylbenzylsulfonium hexafluorophosphate, triphenylsulfonium hexafluorophosphate, methyl diphenylsulfonium tetrafluoroborate, dimethyl phenylsulfonium hexafluorophosphate, and the like.

The aromatic halonium salt may be an aromatic iodonium salt. Examples of the aromatic iodonium salt include, but are not limited to, diphenyliodonium tetrafluoroborate, diphenyliodonium hexafluoroantimonate, butylphenyliodonium hexafluoroantimonate (SP-172 obtained from Asahi denka), and the like.

An amount of the cationic photo initiator may be 1-10 parts by weight, more preferably 1.5-5 parts by weight based on 100 parts by weight of the bisphenol-A-based prepolymer having oxytein functional groups on repeating units thereof. When the amount of the cationic photo initiator is less than 1 part by weight based on 100 parts by weight of the bisphenol-A-based prepolymer having oxytein functional groups on repeating units thereof, a sufficient cross-linking reaction can not be performed. When the amount of the cationic photo initiator is greater than 10 parts by weight based on 100 parts by weight of the bisphenol-A-based prepolymer having oxytein functional groups on repeating units thereof, a higher amount of light energy than light energy appropriate to a layer thickness is required, which thereby reduces the cross-linking speed.

A solvent used in the negative photoresist composition may be at least one selected from a group consisting of γ-butyrolactone, propylene glycol methyl ethyl acetate, tetrahydrofurane, methyl ethyl ketone, methyl isobutyl ketone, cyclophentanone and xylene.

An amount of the solvent may be 30-300 parts by weight, more preferably 50-200 parts by weight based on 100 parts by weight of the bisphenol-A-based prepolymer having oxytein functional groups on repeating units thereof. When the amount of the solvent is less than 30 parts by weight based on 100 parts by weight of the bisphenol-A-based prepolymer having oxytein functional groups on repeating units thereof, viscosity is increased, and thus working efficiency is reduced. When the amount of the solvent is greater than 300 parts by weight based on 100 parts by weight of the bisphenol-A-based prepolymer having oxytein functional groups on repeating units thereof, viscosity of the obtained polymer is decreased, thus making it difficult to form patterns.

Additional additives, photosensitizers, silane coupling agents, fillers, viscosity modifiers, wetting agents, photostabilizers, and the like can be used in the negative photoresist composition. An amount of each of the additional additives may be 0.1-20 parts by weight based on 100 parts by weight of the bisphenol-A-based prepolymer having oxytein functional groups on repeating units thereof.

The photosensitizers absorb light energy and facilitate the transfer of energy to another compound, which can then form radical or ionic initiators. The photosensitizers frequently expand a useful energy wavelength range for photoexposure, and typically are aromatic light absorbing chromophores. In addition, the photosensitizers can also lead to the formation of radical or ionic photoinitiators.

The present general inventive concept also provides a method of manufacturing an inkjet printhead according to the present general inventive concept. In more detail, the method includes forming a heater to heat ink and an electrode to supply current to the heater on a substrate, coating a first negative photoresist composition on the substrate on which the heater and the electrode are formed, and patterning the first negative photoresist composition by photolithography to form a passage forming layer that defines an ink passage, forming a sacrificial layer on the substrate on which the passage forming layer is formed to cover the passage forming layer, planarizing top surfaces of the passage forming layer and the sacrificial layer by a polishing process, coating a second negative photoresist composition on the passage forming layer and the sacrificial layer and patterning the second negative photoresist composition by photolithography to form a nozzle layer having a nozzle, forming an ink supply hole in the substrate, and removing the sacrificial layer, wherein the first and second negative photoresist compositions includes a bisphenol-A-based prepolymer having glycidyl ether functional groups on repeating monomer units thereof and can be the same or different.

The substrate may be a silicon wafer.

The forming of a passage forming layer may include coating the first negative photoresist composition on an entire surface of the substrate to form a first photoresist layer, exposing the first photoresist layer to light using a first photo mask having an ink passage pattern, and developing the first photoresist layer to remove an unexposed portion of the first photoresist layer to form the passage forming layer.

The sacrificial layer can include a positive photoresist or non-photosensitive soluble polymer. The positive photoresist may be an imide-based positive photoresist. The non-photosensitive soluble polymer may be at least one selected from a group consisting of a phenol resin, a polyurethane resin, an epoxy resin, a polyimide resin, an acryl resin, a polyamide resin, a urea resin, a melamin resin, and a silicon resin. The term “soluble” refers to a property of being dissolved by a specific solvent.

In the forming of a sacrificial layer, the sacrificial layer can be formed to have a higher height than that of the passage forming layer. Herein, the sacrificial layer may be formed by spin coating.

In the planarizing of the top surfaces of the passage forming layer and the sacrificial layer, the top surfaces of the passage forming layer and the sacrificial layer may be planarized through a polishing process until the ink passage has a desired height. The polishing process can be a chemical mechanical polishing (CMP) process.

The forming of a nozzle layer may include coating the second negative photoresist composition on the passage forming layer and the sacrificial layer to form a second photoresist layer, exposing the second photoresist layer to light using a second photo mask having a nozzle pattern, and developing the second photoresist layer, thereby removing an unexposed portion of the second photoresist layer to form the nozzle and the nozzle layer.

The forming of an ink supply hole may include coating a photoresist on a rear surface of the substrate, patterning the photoresist to form an etching mask for forming the ink supply hole, and etching a rear surface of the substrate that is exposed by the etching mask to form the ink supply hole. The rear surface of the substrate can be etched by a dry etching process, or a wet etching process using tetramethyl ammonium hydroxide (TMAH) or KOH as an etchant.

As described above, the first and second negative photoresist compositions can further comprise cationic photo initiators and solvents, in addition to the bisphenol-A-based prepolymer having glycidyl ether functional groups on repeating units thereof.

The bisphenol-A-based prepolymer having glycidyl ether functional groups on repeating units thereof in the negative photoresist composition is exposed to actinic rays, such as ultraviolet rays, and thereby can be used to form a cross-linked polymer.

Since the top surface of the sacrificial layer can be planarized, the shape and dimensions of an ink passage can be easily controlled, thereby enhancing uniformity of the ink passage. In addition, a cross-linked polymer forming a chamber and a nozzle layer according to the present general inventive concept is prepared by cross-linking a bisphenol-A-based prepolymer having a plurality of glycidyl ether functional groups on repeating units thereof. Glycidyl ether multi-functional groups are generally arranged at sites of hydrogen atoms of phenolic hydroxyl groups.

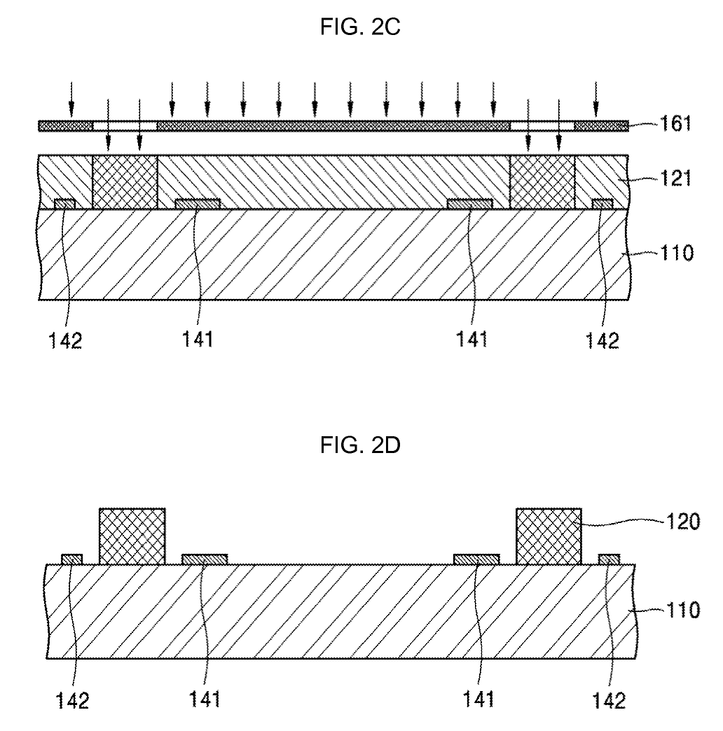

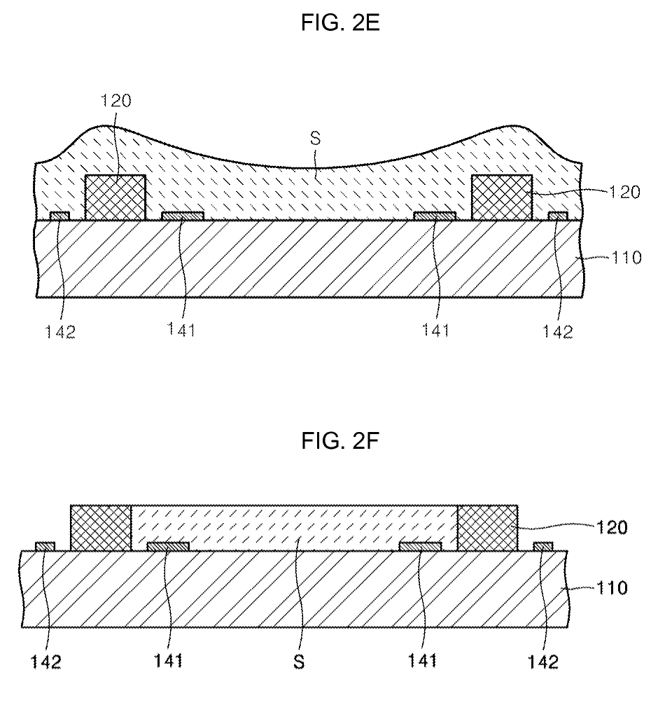

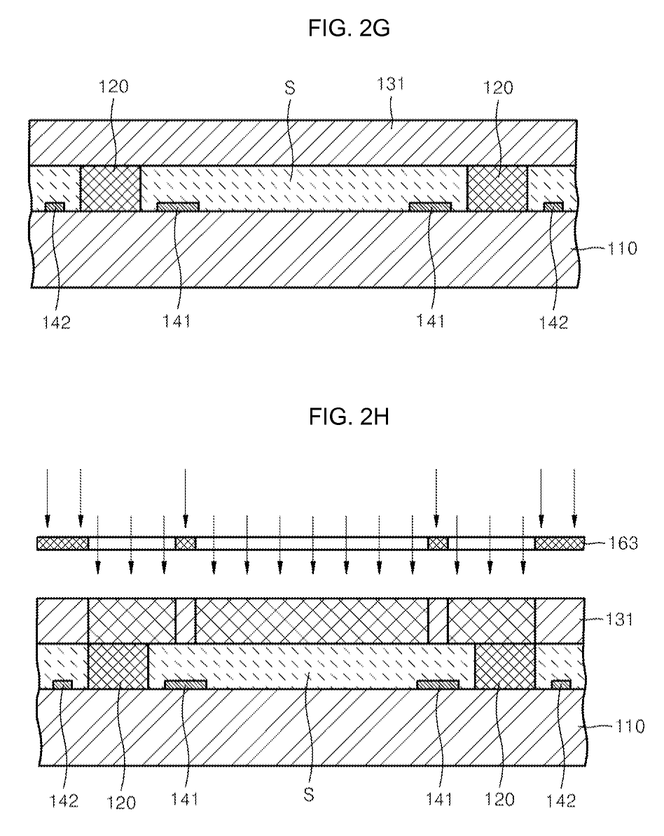

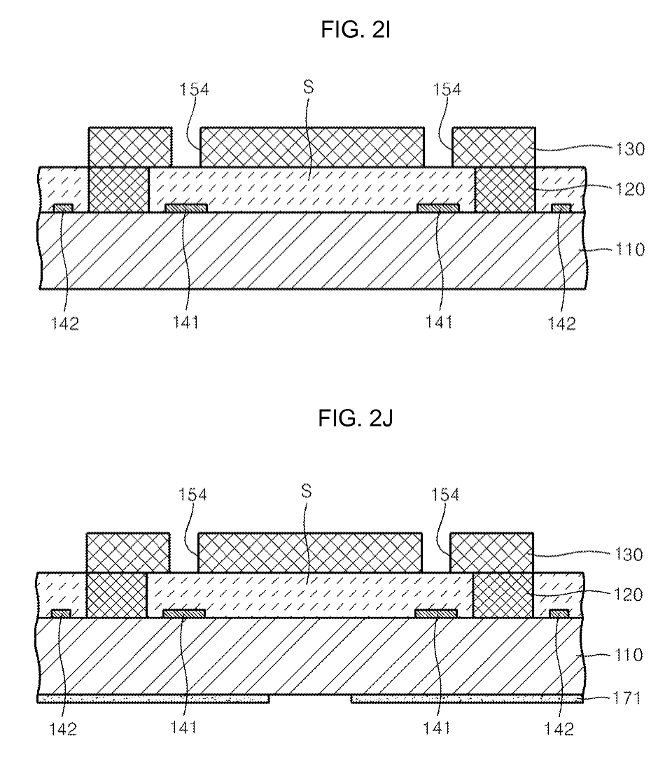

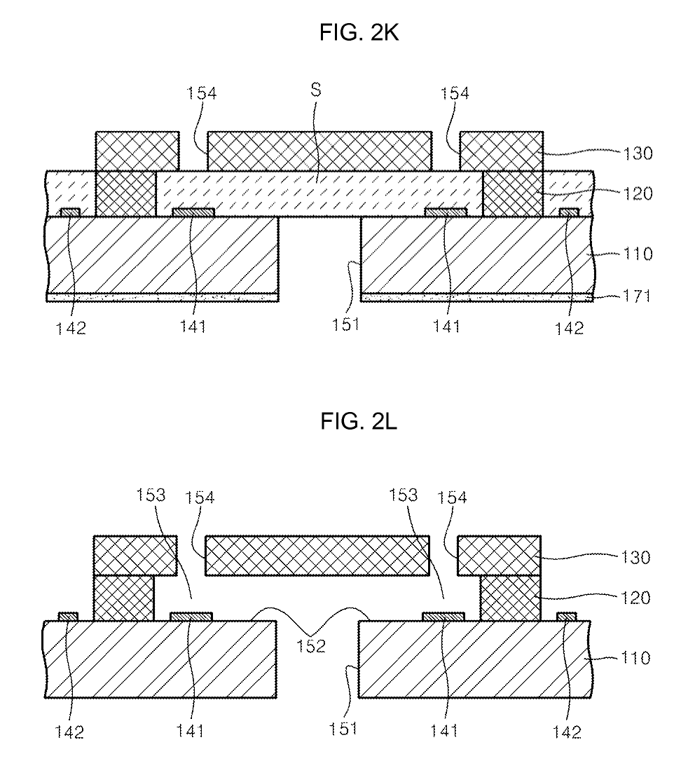

FIGS. 2A through 2L are sectional views illustrating a method of manufacturing an inkjet printhead, according to an embodiment of the present general inventive concept, wherein a passage forming layer and a nozzle layer are formed using a negative photoresist composition containing a bisphenol-A-based prepolymer, and a planarization of a sacrificial layer is performed by a CMP process.

First, referring to FIG. 2A, heaters 141 to heat ink and electrodes 142 to supply current to the heaters 141 are formed on a substrate 110. The substrate 110 can be a silicon wafer. The silicon wafer is widely used in manufacturing semiconductor devices, and is effective for mass-production.

In addition, the heaters 141 can be formed by depositing a resistance heating material, such as tantalum-nitride or tantalum-aluminium alloy, on the substrate 110 using sputtering or chemical vapor deposition, and then patterning the resistance heating material.

The electrodes 142 can be formed by depositing a highly conductive metal material, such as aluminium or aluminium alloy, on the substrate 110 using sputtering, and then patterning the metal material. Although not illustrated, a passivation layer can be formed using silicon oxide or silicon nitride on the heaters 141 and the electrodes 142.

Next, referring to FIG. 2B, a first negative photoresist layer 121 is formed on the substrate 110 on which the heaters 141 and the electrodes 142 are formed. The first negative photoresist layer 121 forms a passage forming layer (120 in FIG. 2D) that surrounds an ink chamber and a restrictor, as will be described later. The first negative photoresist layer 121 is cross-linked by actinic rays, such as ultraviolet rays, and thus, has chemically stable properties against ink. The first negative photoresist layer 121 can be formed using a photoresist composition containing a prepolymer having glycidyl ether functional groups on repeating monomer units thereof, as described above. In particular, the first negative photoresist layer 121 is formed by coating the photoresist composition on a front surface of the substrate 110 to a predetermined thickness. The photoresist composition can be coated on the substrate 110 by spin coating.

Next, referring to FIG. 2C, the first negative photoresist layer 121 is exposed to actinic radiation, preferably ultraviolet rays, using a first photo mask 161 having ink chamber and restrictor patterns. In the exposing operation, an exposed portion of the first negative photoresist layer 121 is cured, and thus obtains chemical resistance and high mechanical strength. On the other hand, unexposed portions thereof are easily dissolved by a developer.

Next, when the first negative photoresist layer 121 is developed, an unexposed portion thereof is removed, as illustrated in FIG. 2D, and a passage forming layer 120 that defines an ink passage is formed.

Next, referring to FIG. 2E, a sacrificial layer S is formed on the substrate 110 to cover the passage forming layer 120. At this time, the sacrificial layer S is formed to have a height higher than that of the passage forming layer 120. The sacrificial layer S can be formed to a predetermined thickness by coating a positive photoresist or non-photosensitive soluble polymer on the substrate 110 by spin coating. The positive photoresist may be an imide-based positive photoresist. When an imide-based positive photoresist is used as a material to form the sacrificial layer S, it is hardly affected by a solvent, and nitrogen gas is not generated during exposure to light. For this, a process in which an imide-based positive photoresist is hard baked at about 140° C. is needed. Also, the sacrificial layer S can be formed to a predetermined thickness by coating an aqueous non-photosensitive soluble polymer on the substrate using a spin coating method, and then baking the aqueous non-photosensitive soluble polymer. The aqueous non-photosensitive soluble polymer may be at least one selected from a group consisting of a phenol resin, a polyurethane resin, an epoxy resin, a polyimide resin, an acryl resin, a polyamide resin, a urea resin, a melamin resin, and a silicon resin.

Next, referring to FIG. 2F, the surfaces of the passage forming layer 120 and the sacrificial layer S are planarized by a chemical mechanical polishing (CMP) process. In detail, the top surfaces of the sacrificial layer S and the passage forming layer 120 are polished by a CMP process until an ink passage with a desired height is obtained. As a result, a height of the top surface of the passage forming layer 120 is the same as that of the top surface of the sacrificial layer S.

Next, referring to FIG. 2G a second negative photoresist layer 131 is formed on the planarized passage forming layer 120 and the sacrificial layer S. The second negative photoresist layer 131 can be formed using a composition containing a bisphenol-A-based prepolymer having glycidyl ether functional groups on repeating monomer units thereof like in the formation of the first negative photoresist layer 121.

The second negative photoresist layer 131 is used to form a nozzle layer (130 in FIG. 2I) as will be described later. The second negative photoresist layer 131 is cross-linked by actinic radiation, such as ultraviolet rays, and thus, has chemically stable properties against ink. In particular, the second negative photoresist layer 131 is formed by coating the composition described above on the passage forming layer 120 and the sacrificial layer S using a spin coating method. At this time, the second negative photoresist layer 131 is formed to have a high enough thickness to obtain a sufficiently long nozzle and to have a high enough strength to withstand a change in a pressure of an ink chamber.

In the previous operation illustrated in FIG. 2F, since the sacrificial layer S and the passage forming layer 120 are planarized to have the same top surface heights, problems in which an edge of the sacrificial layer S is deformed or melted by a reaction between a material used to form the second negative photoresist layer 131 and a material used to form the sacrificial layer S do not occur. Accordingly, the second photoresist layer 131 can be coupled to the top surface of the passage forming layer 120.

Next, referring to FIG. 2H, the second negative photoresist layer 131 is exposed to light using a second photo mask 163 having a nozzle pattern and developed to remove an unexposed portion of the second negative photoresist layer 131. As a result, nozzles 154 are formed and a portion of the second negative photoresist layer 131 cured by exposure to light remains to form a nozzle layer 130, as illustrated in FIG. 2I. At this time, when the sacrificial layer S comprises an imide-based positive photoresist as described above, nitrogen gas is not generated although the sacrificial layer S is exposed to light through the second negative photoresist layer 131. Therefore, the nozzle layer 130 can be prevented from being deformed by nitrogen gas.

Next, referring to FIG. 2J, an etching mask 171 to form an ink supply hole (151 in FIG. 2K) is formed on a rear surface of the substrate 110. The etching mask 171 can be formed by coating a positive or negative photoresist on the substrate 110, and then patterning the positive or negative photoresist.

Next, referring to FIG. 2K, the substrate 110 exposed by the etching mask 171 is etched from the rear surface thereof to be perforated to thereby form an ink supply hole 151, followed by removing the etching mask 171. The process of etching the rear surface of the substrate 110 can be performed by dry etching with plasma. The process of etching the rear surface of the substrate 110 can also be performed by wet etching using tetramethyl ammonium hydroxide (TMAH) or KOH as an etchant.

Lastly, when the sacrificial layer S is removed using a solvent, as illustrated in FIG. 2L, ink chambers 153 and restrictors 152 that are surrounded by the passage forming layers 120 are formed, and electrodes 142 to supply current to the heaters 141 are exposed. This completes manufacture of an inkjet printhead having a structure as illustrated in FIG. 2L.

Hereinafter, the present general inventive concept will be described in further detail with reference to the following examples. These examples are only for illustrative purposes and are not intended to limit the scope of the present general inventive concept.

### Synthesis Example 1

### Synthesis of toluene-4-sulfonic acid-3-methyl-oxetan-3-yl methyl ester

Toluene-4-sulfonic acid-3-methyl-oxetan-3-yl methyl ester represented by Formula 13 below was synthesized according to Reaction Scheme 1 below.

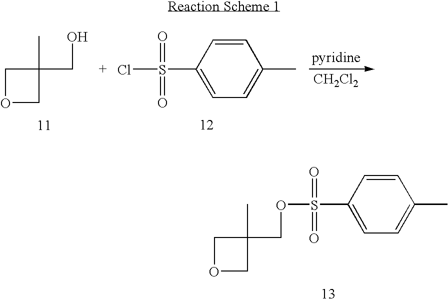

### Synthesis Example 2

### Synthesis of Oxetan-Containing Compound Represented by Formula 2

An oxetan-containing compound of Formula 2 below was synthesized according to Reaction Scheme 2 below.

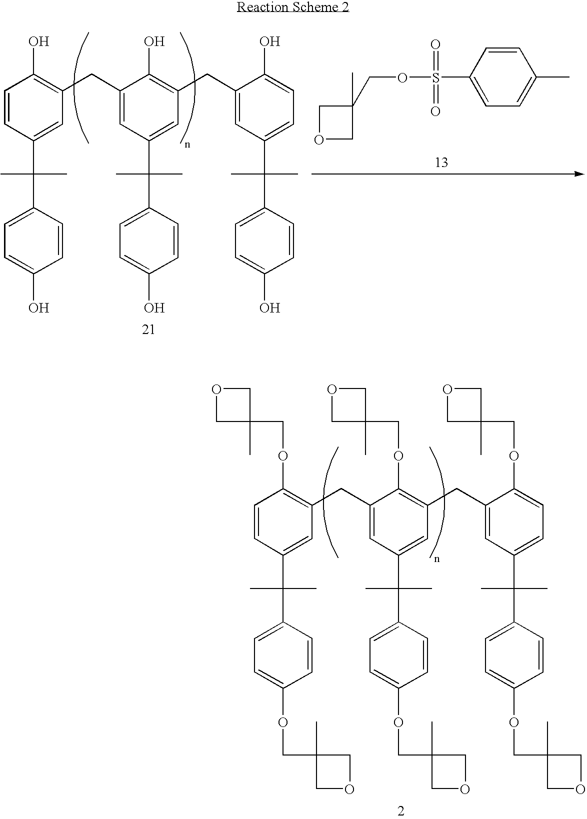

where n is an integer of 2.

### Synthesis Example 3

### Preparation of Negative Photoresist Composition

30 g of PGMEA (manufactured by AZ EM Co.) and 3 g of SP-172 (manufactured by Asahi Denka Korea Chemical Co.) were added to a jar to prepare a resist solution. Then, 40 g of the oxetan-containing compound of Formula 2 prepared in Synthesis Example 2 was added to the jar, and the solution was mixed in a roller for about 24 hours to prepare a negative photoresist composition.

### Example 1

A heater pattern 141 (thickness of about 500 Å) of tantalum nitride and an electrode pattern 142 (thickness of about 500 Å) of AlSiCu alloy (1 wt % or less of each of Si and Cu) were formed on a 6-inch silicon wafer 110 using a conventional sputtering process and photolithography process (refer to FIG. 2A).

Next, as illustrated in FIG. 2B, the synthesized negative photoresist composition of synthesis example 3 was spin coated on a front surface of a silicon wafer on which the heater pattern and the electrode pattern were formed for 40 seconds at 2000 rpm, and baked for 7 minutes at 95° C. to form a first negative photoresist layer having a thickness of about 10 μm. Subsequently, as illustrated in FIG. 2C, the first negative photoresist layer was exposed to i-line ultraviolet rays using a first photo mask having predetermined ink chamber and restrictor patterns. At this time, an exposure dose was adjusted to 130 mJ/cm². The silicon wafer was then baked for 3 minutes at 95° C., dipped into a PGMEA developer for development, and rinsed using isopropanol for 20 seconds. In such a manner, a passage forming layer (120 in FIG. 2D) was completed.

Next, as illustrated in FIG. 2E, an imide-based positive photoresist (manufacturer: TORAY, product: PW-1270) was spin coated on a front surface of the silicon wafer on which the passage forming layer pattern 120 was formed for 40 seconds at 1000 rpm, and baked for 10 minutes at about 140° C. to form a sacrificial layer S. The thickness of the sacrificial layer S was adjusted such that the overcoated thickness of the sacrificial layer S on the passage forming layer pattern 120 was about 5 μm.

Next, as illustrated in FIG. 2F, the top surfaces of the passage forming layer pattern 120 and the sacrificial layer S were planarized using a chemical mechanical polishing process. For this, the silicon wafer was supplied to a polishing pad of a polishing plate (manufacturer: JSR, product: JSR FP 8000) such that the sacrificial layer S faced the polishing pad. Subsequently, the silicon wafer was pressed on the polishing pad by press polishing using a backing pad at a pressure of 10-15 kPa. While a polishing slurry (FUJIMI Corporation, POLIPLA 103) was supplied on the polishing pad, a press head was rotated against the polishing pad. At this time, a revolution velocity of each of the press head and polishing pad was 40 rpm. The backing pad was made of a material having a Shore D hardness in the range of 30-70. While an etch rate was adjusted to 5-7 μm/min, the sacrificial layer S was removed until about 1 μm of the top surface of the passage forming layer pattern 120 was removed, and was thereby planarized.

A nozzle layer pattern 130 was formed on the silicon wafer 110 on which the passage forming layer pattern 120 and the sacrificial layer S using the negative photoresist composition prepared in Synthesis Example 3 and a photo mask 163 under the same conditions as those in the process of forming the passage forming layer pattern 120 (refer to FIGS. 2G, 2H and 2I).

As illustrated in FIG. 2J, an etching mask 171 was formed on a rear surface of the silicon wafer 110 using a conventional photolithography method in order to form an ink supply hole 151. Subsequently, as illustrated in FIG. 2K, the silicon wafer was plasma etched from a rear surface of the silicon wafer 110 exposed by the etching mask 171 to form the ink supply hole 151, and then the etching mask 171 was removed. At this time, a plasma etching device had a power of 2000 Watts, an etching gas was a mixed gas of SF₆ and O₂ (mixed volume ratio of 10:1), and an etch rate of the silicon wafer was 3.7 μm/min.

Lastly, the silicon wafer was dipped in a methyl lactate solvent for 2 hours to remove the sacrificial layer S. As a result, as illustrated in FIG. 2L, ink chambers 153 and restrictors 152 surrounded by the passage forming layer 120 were formed in a space in which the sacrificial layer S was removed. In such a way, an inkjet printhead having the structure as illustrated in FIG. 2I was completed.

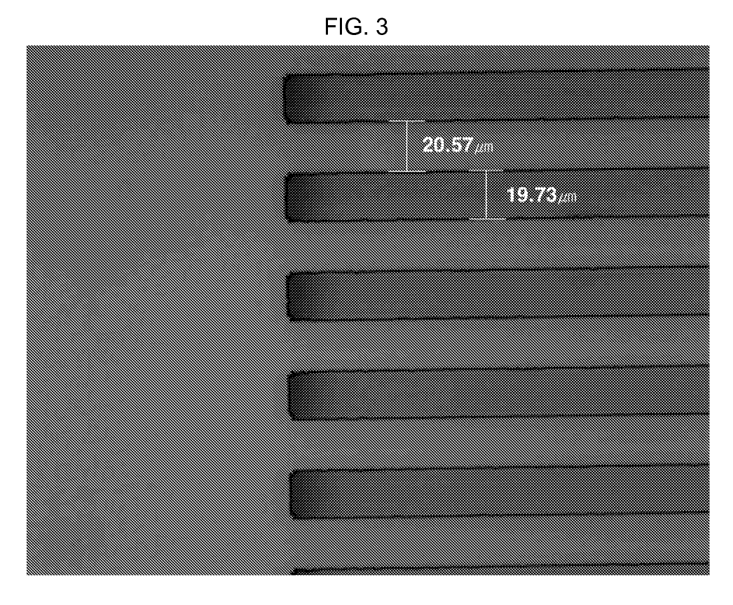

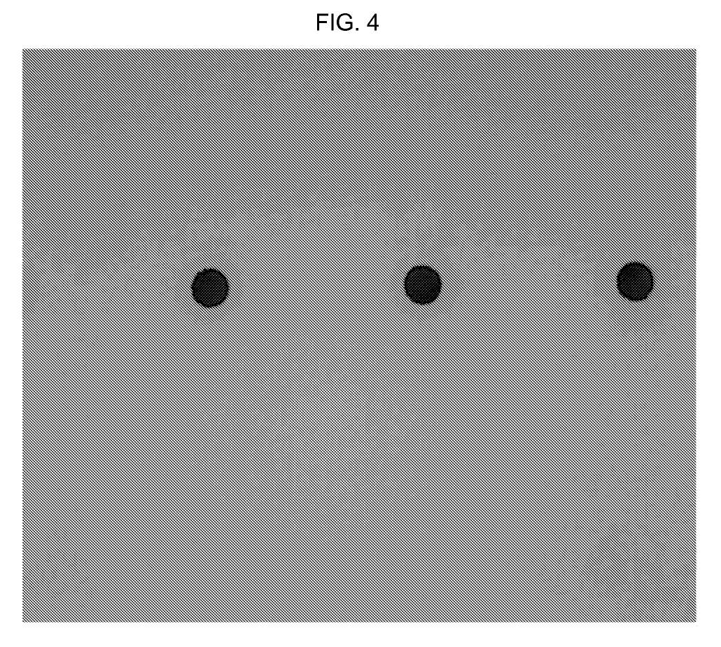

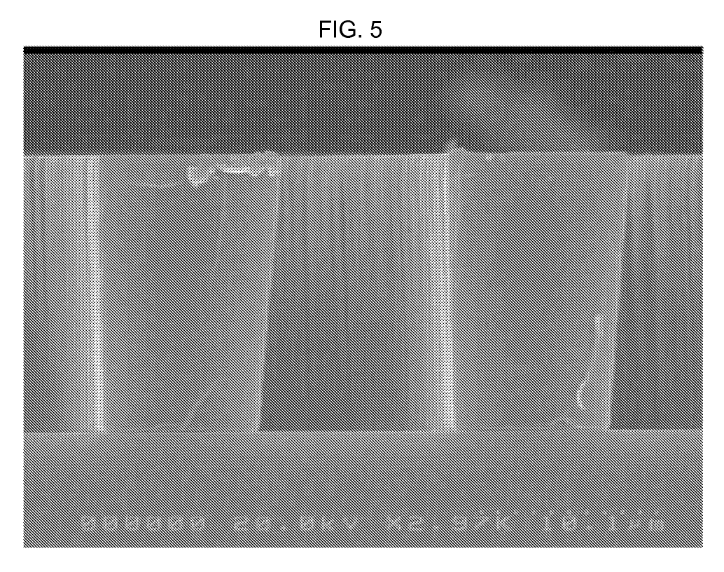

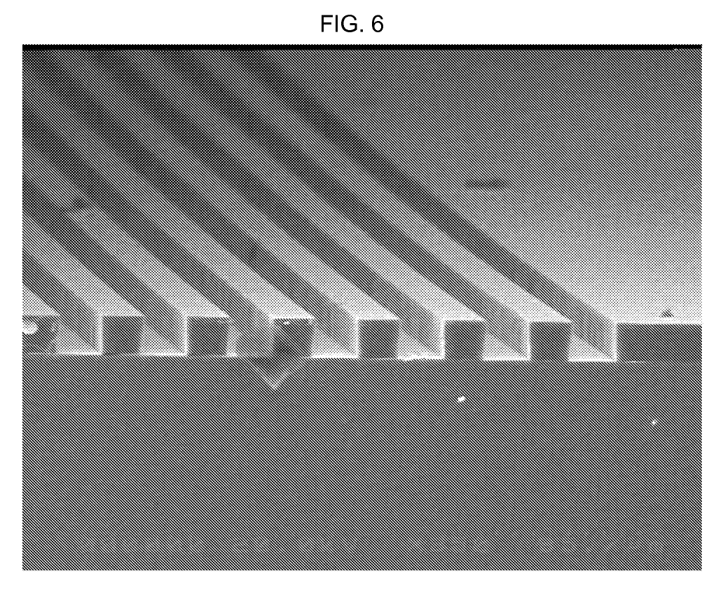

As describe above, an inkjet printhead was manufactured using the negative photoresist composition prepared in Synthesis Example 3 as a first negative photoresist composition and second negative photoresist composition. FIG. 3 is an optical microscopic image of 20 μm line/space (L/S) patterns, FIG. 4 is an electronic microscopic image of an ink supply hole positioned on a rear surface of a printhead, FIG. 5 is an electron microscopic image showing a cross-section of nozzles, and FIG. 6 is an optical microscopic image of 20 μm line/space (L/S) patterns.

In particular, from the electronic microscopic image of FIG. 3, it can be seen that 20 μm line/space (L/S) patterns had uniform widths of 20.57 μm and 19.73 μm, respectively.

As can be seen from FIGS. 3 through 6, the inkjet printhead obtained according to the present general inventive concept has a very small thickness difference in a nozzle layer. In addition, since a bisphenol-A-based prepolymer having oxytein functional groups on repeating units thereof is used as a resist composition, a rapid polymerization can be achieved, and cracks and the like do not occur so that durability is improved.

Although a few embodiments of the present general inventive concept have been shown and described, it will be appreciated by those skilled in the art that changes may be made in these embodiments without departing from the principles and spirit of the general inventive concept, the scope of which is defined in the appended claims and their equivalents.

What is claimed is:

1. A negative photoresist composition comprising:
a bisphenol-A-based prepolymer having oxytein functional groups on repeating units thereof;
a cationic photo initiator;
and a solvent.

2. The negative photoresist composition of claim 1, wherein amounts of the cationic photo initiator and the solvent are 1-10 parts by weight and 30-300 parts by weight, respectively, based on 100 parts by weight of the bisphenol-A-based prepolymer.

3. The negative photoresist composition of claim 1, wherein the bisphenol-A-based prepolymer is a prepolymer represented by Formula 1 below: 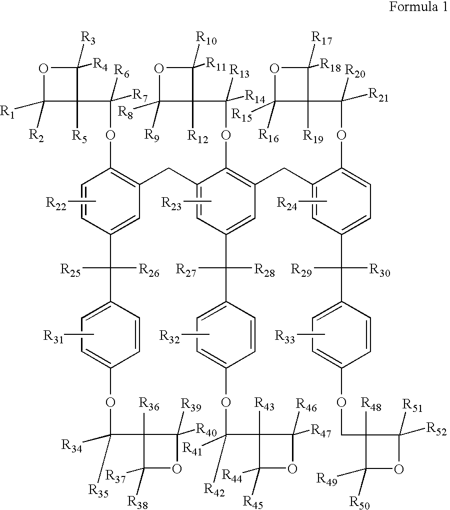
wherein n is an integer of 1-20, and R₁ through R₅₂ are each independently one of a halogen atom, a carboxyl group, an amino group, a nitro group, a cyano group, a substituted or unsubstituted C₁-C₂₀ alkyl group, a substituted or unsubstituted C₁-C₂₀ alkoxy group, a substituted or unsubstituted C₂-C₂₀ alkenyl group, a substituted or unsubstituted C₂-C₂₀ alkynyl group, a substituted or unsubstituted C₁-C₂₀ heteroalkyl group, a substituted or unsubstituted C₆-C₃₀ aryl group, a substituted or unsubstituted C₇-C₃₀ arylalkyl group, a substituted or unsubstituted C₅-C₃₀ heteroaryl group, and a substituted or unsubstituted C₃-C₃₀ heteroarylalkyl group.

4. The negative photoresist composition of claim 3, wherein the bisphenol-A-based prepolymer of Formula 1 is a prepolymer represented by Formula 2 below: 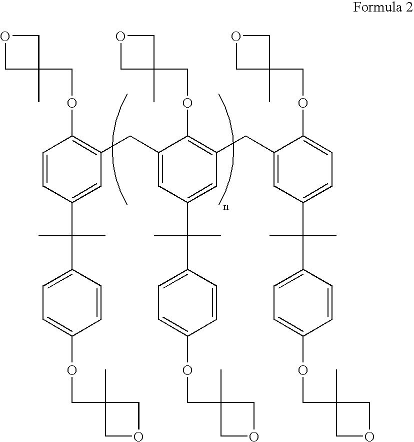
where n is an integer in the range of 1-20.

5. The negative photoresist composition of claim 1, wherein the cationic photo initiator is one of an aromatic halonium salt and an aromatic sulfonium salt.

6. The negative photoresist composition of claim 1, wherein the solvent is at least one selected from a group consisting of γ-butyrolactone, propylene glycol methyl ethyl acetate, tetrahydrofurane, methyl ethyl ketone, methyl isobutyl ketone, cyclophentanone, and xylene.

7. A method of manufacturing an inkjet printhead, the method comprising:
forming a heater to heat ink and an electrode to supply current to the heater on a substrate;
coating a first negative photoresist composition on the substrate on which the heater and the electrode are formed, and patterning the first negative photoresist composition by photolithography to form a passage forming layer that defines an ink passage;
forming a sacrificial layer on the substrate on which the passage forming layer is formed to cover the passage forming layer;
planarizing top surfaces of the passage forming layer and the sacrificial layer by a polishing process;
coating a second negative photoresist composition on the passage forming layer and the sacrificial layer, and patterning the second negative photoresist composition by photolithography to form a nozzle layer having a nozzle;
forming an ink supply hole in the substrate; and
removing the sacrificial layer,
wherein the first and second negative photoresist compositions are each independently negative photoresist compositions comprising:
a bisphenol-A-based prepolymer having oxytein functional groups on repeating units thereof,
a cationic photo initiator,
and a solvent.

8. The method of claim 7, wherein the polishing process is a chemical mechanical polishing process.

9. The method of claim 7, wherein the substrate is a silicon wafer.

10. The method of claim 7, wherein the forming of the passage forming layer comprises:
coating the first negative photoresist composition on an entire surface of the substrate to form a first photoresist layer;
exposing the first photoresist layer to light using a first photo mask having an ink passage pattern; and
developing the first photoresist layer to remove an unexposed portion of the first photoresist layer to form the passage forming layer.

11. The method of claim 7, wherein the sacrificial layer comprises one of a positive photoresist and a non-photosensitive soluble polymer.

12. The method of claim 11, wherein the positive photoresist is an imide-based positive photoresist.

13. The method of claim 11, wherein the non-photosensitive soluble polymer is at least one selected from a group consisting of a phenol resin, a polyurethane resin, an epoxy resin, a polyimide resin, an acryl resin, a polyamide resin, an urea resin, a melamin resin, and a silicone resin.

14. The method of claim 7, wherein in the forming of the sacrificial layer, a height of the sacrificial layer is greater than that of the passage forming layer.

15. The method of claim 7, wherein in the forming of the sacrificial layer, the sacrificial layer is formed by spin coating.

16. The method of claim 7, wherein the planarizing of the top surfaces of the passage forming layer and the sacrificial layer comprises:
polishing the top surfaces of the passage forming layer and the sacrificial layer using a polishing process until the ink passage has a desired height.

17. The method of claim 7, wherein the forming of the nozzle layer comprises:
coating a second negative photoresist composition on the passage forming layer and the sacrificial layer to form a second photoresist layer;
exposing the second photoresist layer to light using a second photo mask having a nozzle pattern; and
developing the second photoresist layer to remove an unexposed portion of the second photoresist layer to form the nozzle and the nozzle layer.

18. The method of claim 7, wherein the forming of the ink supply hole comprises:
coating a photoresist on a rear surface of the substrate;
patterning the photoresist to form an etching mask to form the ink supply hole; and
etching a rear surface of the substrate that is exposed by the etching mask to form the ink supply hole.

19. The method of claim 18, wherein the rear surface of the substrate is etched by dry etching with plasma.

20. The method of claim 18, wherein the rear surface of the substrate is etched by wet etching using one of tetramethyl ammonium hydroxide (TMAH) and KOH as an etchant.

21. An inkjet printhead manufactured by a method of manufacturing an inkjet printhead using a negative photoresist composition comprising a bisphenol-A-based prepolymer having oxytein functional groups on repeating units thereof, the method comprising:
forming a heater to heat ink and an electrode to supply current to the heater on a substrate;
coating a first negative photoresist composition on the substrate on which the heater and the electrode are formed, and patterning the first negative photoresist composition by photolithography to form a passage forming layer that defines an ink passage;
forming a sacrificial layer on the substrate on which the passage forming layer is formed to cover the passage forming layer;
planarizing top surfaces of the passage forming layer and the sacrificial layer by a polishing process;
coating a second negative photoresist composition on the passage forming layer and the sacrificial layer, and patterning the second negative photoresist composition by photolithography to form a nozzle layer having a nozzle;
forming an ink supply hole in the substrate; and
removing the sacrificial layer,
wherein the first and second negative photoresist compositions are each independently negative photoresist compositions comprising:
the bisphenol-A-based prepolymer having oxytein functional groups on repeating units thereof,
a cationic photo initiator,
and a solvent.

22. An inkjet printhead, comprising:
a chamber layer to define an ink passage, the ink passage defining a plurality of ink chambers and restrictors; and a
nozzle layer defining a plurality of nozzles, the nozzles disposed to correspond to the plurality of ink chambers,
wherein the chamber layer and the nozzle layer are each independently formed of a negative photoresist comprising:
a bisphenol-A-based prepolymer having oxytein functional groups on repeating units thereof,
a cationic photo initiator,
and a solvent.

23. The inkjet printhead of claim 22, wherein:
the chamber layer is formed by coating a first negative photoresist composition on a substrate, and patterning the first negative photoresist composition by photolithography to form the chamber layer, and
the nozzle layer is formed by coating a second negative photoresist composition on the chamber layer, and patterning the second negative photoresist composition by photolithography to form the nozzle layer.
